(19) United States
(12) Patent Application Publication
(10) Pub. No.: US 2008/0053819 A1
(43) Pub. Date: Mar. 6, 2008

(54) Method of fabricating conductive carbon thin-film of high-hardness and application of the carbon thin-film as electrode for thin-film electro-luminescent device

(75) Inventors: Byungyou Hong, Seoul (KR); Yongseob Park, Suwon (KR); Hyungjun Cho, Pohang (KR)

Correspondence Address: EDWARDS ANGELL PALMER & DODGE LLP, P.O. BOX 55874, BOSTON, MA, 02205, US

(73) Assignee: Sungkyunkwan University Foundation for Corporate Collaboration, Suwon (KR)

(21) Appl. No.: 11/706,933

(22) Filed: Feb. 13, 2007

(30) Foreign Application Priority Data
Sep. 5, 2006 (KR) 10-2006-0085225

(51) Int. Cl. C23C 14/00

(52) U.S. Cl. 204/192.1

(57) ABSTRACT

The present invention provides a method of fabricating a carbon thin-film having high conductivity and high hardness, comprising the steps of: supplying argon (Ar) to the chamber as sputtering gas; maintaining the initial vacuum of the chamber at about 10⁻⁶ Torr; forming deposition pressure of about 10⁻³ Torr so as to activate plasma; and applying negative DC bias to the substrate, and a method of fabricating a thin-film electroluminescent device comprising the steps of: providing a transparent TCO or ITO substrate; forming a phosphor layer on the top of the transparent substrate; forming an insulation layer on the top of the phosphor layer through vacuum deposition; and forming a carbon thin-film electrode through closed-field unbalanced magnetron sputtering.

### CROSS-REFERENCE TO RELATED APPLICATION

The present application claims, under 35 U.S.C. §119(a), the benefit of the filing date of Korean Patent Application No. 10-2006-0085225 filed on Sep. 05, 2006, the entire contents of which are hereby incorporated by reference.

### BACKGROUND OF THE INVENTION

1. Field of the invention

The present invention relates to a method of fabricating a carbon thin-film. More particularly, it relates to a method for growing a carbon thin-film having high conductivity and superior physical properties.

2. Background Art

With the development of the information society, the importance of the exchange of information has increased. In this regard, display devices for displaying image information which are aesthetically pleasing to people occupy an importance position. Recently, with the tendency of demanding flat display devices which are easy to miniaturize and carry, LCDs (Liquid Crystal Displays), PDPs (Plasma Display Panels), FEDs (Field Emission Displays), and ELDs (Electro-Luminescent Device), which are capable of being extremely thin, have been gradually commercialized. Such light-emitting devices should be driven with suitably low voltage and low power consumption, and should be thin compared to the volume thereof. In particular, electro-luminescent devices are driven with low power consumption. Since electroluminescent devices do not have a light guide plate, they emit light widely and evenly. Such devices are advantageous in price competitiveness because they have a simple structure which can be easily fabricated. Another Furthermore, such devices have an advantage in that they can be provided in a thin, mechanically flexible structure.

Metal electrodes formed from gold, silver or the like are conventionally employed as electrodes for such thin-film EL devices. However, such electrodes have problems in that the fabricating processes are complicated, the manufacturing costs are high, and the metal electrodes are apt to be worn and have corrosive property, which causes oxidation of the thin-film and produces moisture.

Diamond-like carbon (DLC) films has been suggested as electrodes. However, a DLC film fabricated using a conventional PVD or CVD apparatus usually contains a large quantity of hydrogen, which exhibits insulation property, by which conductivity of the DLC thin-film is relatively weakened, although such a DLC thin-film exhibits some superior physical properties. A suggested way to solve this problem was to dope the DLC thin-film with a metal so as to increase conductivity. The suggested way, however, has disadvantages in that the manufacturing process is complicated and the manufacturing costs increase. Furthermore, because deposition of such a DLC thin-film according to a conventional method is performed at high temperatures, the structure of the thin-film can be deteriorated, which makes it difficult or impossible to meet the required physical properties of the film.

Therefore, it has been proposed to employ a carbon thin-film as an electrode of a thin-film electroluminescent device so as to achieve superior physical properties of the carbon thin-film, such as a low frictional coefficient, smooth surface, high strength, corrosion resistance, oxidation resistance, etc. In particular, it has been proposed to fabricate a carbon electrode having special properties of a carbon thin-film, i.e. low resistivity and high conductivity, and to directly employ such a carbon electrode as an electrode of a thin-film electroluminescent device in lieu of a metal electrode formed from gold or silver. By this arrangement, the manufacturing costs can be reduced and the manufacturing process can be simplified, thereby allowing the carbon thin-film to be used as a competitive electrode. However, no conventional techniques meet such requirements.

### SUMMARY OF THE INVENTION

Accordingly, the present invention has been made to solve the above-mentioned problems occurring in the prior art.

An object of the present invention is to provide a method of growing a carbon thin-film which allows a DLC to have high conductivity while maintaining the superior physical properties thereof.

Another object of the present invention is to introduce a new conductive material as an electrode for a thin-film EL device and to employ a conductive carbon electrode tailored to be suitable for various electronic devices in anticipation of the improvement of physical and electrical properties of the devices.

In order to achieve the above-mentioned objects, the present invention, in one aspect, provides a method of fabricating a carbon thin-film having high conductivity and high hardness by using a closed-field unbalanced magnetron sputtering apparatus.

In a preferred embodiment, the closed-field unbalanced magnetron sputtering apparatus comprises: a chamber and an evacuating means for maintaining a vacuum condition in the chamber. The chamber includes a substrate support means, a jig for fixing the substrate support means, a gas supply means, a DC bias power supply, and a cooling line.

Preferably, the closed-field unbalanced magnetron sputtering apparatus may use as a sputtering target a graphite target attached to an electromagnetic power unit.

The jig is applied a negative DC bias so that carbon ions within plasma can easily arrive at the substrate.

A preferred method of the present invention may comprise the steps of: supplying argon (Ar) to the chamber as sputtering gas; maintaining the initial vacuum of the chamber at about 10⁻⁶ Torr; forming deposition pressure of about 10⁻³ Torr so as to activate plasma; and applying negative DC bias to the substrate.

In such preferred method, the carbon thin-film may preferably have a thickness of about 200 nm.

Preferably, the carbon thin-film may have resistivity of 5 mΩ·cm or lower.

Suitably, the sputtering may be performed at room temperature.

In another aspect, the present invention provides a method of fabricating a carbon thin-film comprising the steps of: mounting a flexible substrate on a substrate support within a vacuum chamber by forming the flexible substrate on a silicon or glass substrate and washing the flexible substrate with organic solvent; maintaining the initial vacuum of the vacuum chamber at about 10⁻⁶ Torr and then supplying argon gas from a gas supply system; maintaining pressure within the vacuum chamber at 10⁻³ Torr, thereby activating plasma; and applying negative DC bias to the substrate support from a DC bias power supply so that carbon ions existing in the plasma can easily arrive at the flexible substrate, thereby forming a conductive carbon thin-film having a predetermined resistivity.

Preferably, the flexible substrate can be selected from the group consisting of polyimide (Kapton), polyethylenenappthalate (PEN) and polyester (PET).

In a further aspect, the present invention provides an electroluminescent device comprising as an electrode a carbon thin-film fabricated by the above-described methods.

Suitably, the electroluminescent device can be formed in a structure of a TCO or ITO glass/a phosphor/an insulator/a conductive thin-film electrode.

In still another aspect, the present invention provides a method of fabricating a thin-film electroluminescent device comprising the steps of: providing a transparent TCO or ITO substrate; forming a phosphor layer on the top of the transparent substrate; forming an insulation layer on the top of the phosphor layer through vacuum deposition; and forming a carbon thin-film electrode through closed-field unbalanced magnetron sputtering.

Preferably, the transparent substrate can be formed from an In—O or Sn—O system.

The electrode may suitably be patterned by using metal shadow mask method.

Also preferably, the insulation film can be formed by depositing Si₃N₄ or SiO₂ in a thickness of about 300 nm through plasma-enhanced chemical vapor deposition.

A preferred thickness of the phosphor layer deposited is about 600 nm.

### BRIEF DESCRIPTION OF THE DRAWINGS

The above and other objects, features and advantages of the present invention will be more apparent from the following detailed description taken in conjunction with the accompanying drawings, in which:

FIG. 1 is a schematic cross-sectional view of a carbon thin-film structure according to the present invention;

FIG. 2 shows a closed-field unbalanced magnetron sputtering apparatus for fabricating a carbon thin-film using two graphite targets;

FIG. 3 shows a structure of an electroluminescent device coated with carbon thin-films as an electrode; and

FIG. 4 is a graph showing resistivity of a carbon thin-film fabricated by the present invention.

### DETAILED DESCRIPTION

According to the present invention, a carbon thin-film is grown through closed-field unbalanced magnetron sputtering process. Since closed-field unbalanced magnetron sputtering process can be performed entirely at a low temperature, it is possible to solve a problem related to the temperature of a flexible substrate of an electronic device, which requires deposition performed at room temperature, and the deposition can be uniformly executed on a large area in consideration of commercialization of the carbon thin-film. In particular, if a closed-field unbalanced magnetron sputtering apparatus is employed for high-speed deposition, it is possible to deposit a thicker film within a shorter time, and to exclude the influence of temperature caused by plasma. One technical feature of the present invention is that a conductive thin-film can be fabricated without doping a third material.

The present invention fabricates a conductive carbon thin-film of high-hardness on a silicon or glass substrate by using closed-field unbalanced magnetron sputtering process, which enables deposition on a large area exceeding 4 inches. The closed-field unbalanced magnetron sputtering process is advantageous in that the carbon thin-film can be thickly grown within a short time period with a high growing rate of about 170 nm/minute, and due to the short time period of deposition, the influence of plasma on a substrate can be minimized, whereby the process can be executed at a low temperature, protecting the substrate.

According to the closed-field unbalanced magnetron sputtering process, the sputtering field is increased by using two graphite targets, and an amorphous carbon thin-film, which does not contain hydrogen, can be fabricated because argon (Ar) is employed as the sputtering gas. When forming the carbon thin-film, the initial vacuum is formed at a high vacuum level of about 10⁻⁶ Torr, and the deposition pressure of about 10⁻³ Torr is developed so as to activate plasma. By applying negative DC bias to a jig, to which the substrate is affixed, the probability that carbon ions in the plasma can arrive at the substrate is increased, thereby enabling high-speed deposition. In addition, the entire process is performed at room temperature, thereby excluding the influence of temperature on the carbon thin-film. Only considering the influence of negative DC bias, the conductive carbon thin-film is fabricated with reference to a thickness of 200 nm.

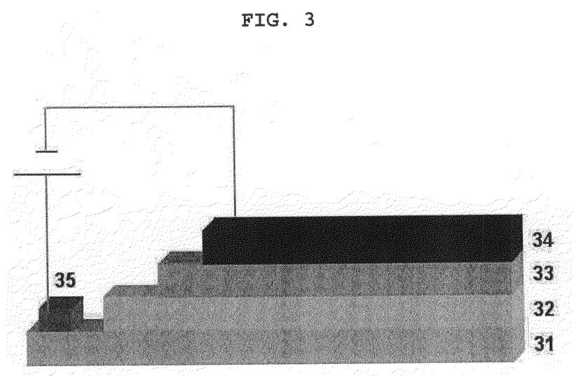

A structure of a thin-film electroluminescent device according to the present invention is illustrated in FIG. 3 by way of an example. The method of fabricating such a thin-film electroluminescent device includes steps of: providing a transparent (ITO or TCO) substrate, forming a phosphor layer on the top of the substrate, forming an insulation material (oxide or nitride) layer on the top of the phosphor layer through vacuum deposition, and forming a conductive carbon thin-film electrode on the top of the insulation material layer through sputtering deposition, the electric resistivity of the conductive carbon thin-film electrode being equal to or lower than 3 mΩ·cm. Although a thin-film electrode is generally made of an opaque metal electrode formed from aluminum (Al), molybdenum (Mo), nickel (Ni), or the like, the present invention employs a conductive carbon thin-film as an electrode, wherein light incident on a transparent ITO (indium tin oxide) substrate sequentially passes through a light-emitting layer and an insulation layer, and then the light is reflected by the carbon thin-film electrode, thereby producing an electroluminescent effect.

Hereinafter, preferred embodiments of the present invention will be described with reference to the accompanying drawings. In the following description and drawings, the same reference numerals are used to designate the same or similar components.

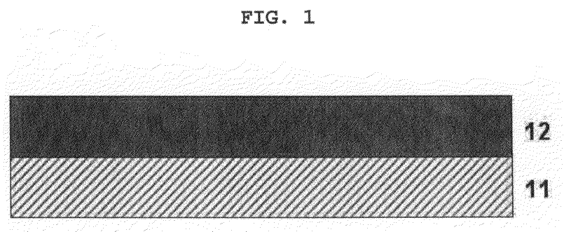

FIG. 1 shows an embodiment of a carbon thin-film structure according to the present invention. As shown in FIG. 1, a conductive carbon thin-film structure of high-hardness is generally formed on a silicon or glass substrate 11 and is used in a state in which the thin-film structure is engaged with an insulation layer of a thin-film electroluminescent device. Occasionally, the substrate 11 may have undergone a pre-processing procedure so as to coat a metallic film on the top surface thereof. In the present invention, the thin-film 12 is a conductive carbon thin-film synthesized at a low temperature by applying negative DC bias without being affected by hydrogen.

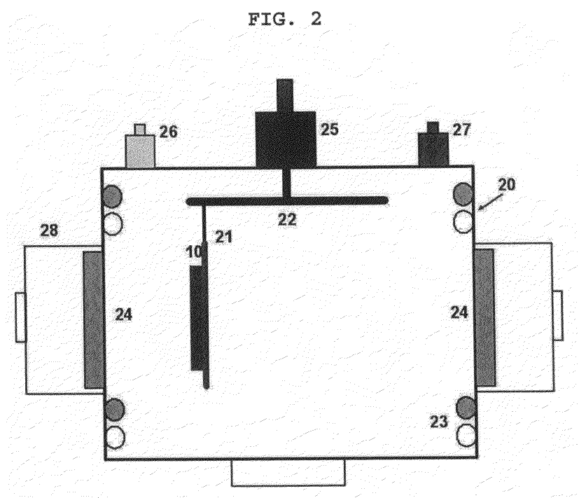

FIG. 2 is a schematic view of an apparatus for fabricating a carbon thin-film according to the present invention. In the carbon thin-film fabrication apparatus, a substrate support 21 is arranged in a vacuum chamber 20, and a jig 22 is arranged on the top of the substrate support 21 so as to affix the support 21. In addition, the jig 22 is directly connected to a DC bias-power supply 25. In order to perform the entire process for fabricating a carbon thin-film, a cooling line 23 is necessarily provided so as to reduce the heat generated during sputtering, wherein the chamber wall is configured in such a way that coolant continuously flows through the cooling line 23 so as to prevent the inside of the chamber from being heated over a predetermined level of temperature. Although not shown in the drawing, a vacuum gauge is provided so as to maintain a vacuum condition suitable for coating inside of the chamber 20.

A pressure gauge is also provided within the vacuum chamber 20 so as to measure the pressure of the vacuum chamber 20. The measurement values of the pressure gauge indicate the pressure within the vacuum chamber 20 and the amount of gases flowing into or out from the vacuum chamber 20, which should be maintained at a proper level. Gas supply systems 26 and 27 supply gases, such as argon (Ar), that are required for coating a thin-film on the substrate, into the vacuum chamber 20. The DC bias power supply 25 is connected to the jig 22 in the vacuum chamber 25 so as to provide power for generating plasma within the vacuum chamber 20, wherein the power supply 25 includes a matching circuit interposed between the vacuum chamber 20 and the power supply 25 so as to tune impedance between them, thereby controlling the generation of plasma. A graphite target is used as a magnetron sputter target 24, and a plasma field is formed by electromagnetic power units 28 attached to the opposite sides, respectively.

Next, a preferred method of coating a carbon thin-film on the substrate 10 arranged on the substrate support 21 will be described, wherein the method is performed by using an above-described carbon thin-film fabrication apparatus.

At first, a silicon substrate, a glass substrate, or a flexible substrate may be employed as the substrate, wherein the flexible substrate may be formed from polyimide (Kapton), polyethylenenappthalate (PEN), polyester, etc. The substrate is washed with an organic solvent and then mounted on the substrate support 21 within the vacuum chamber 20. Next, the initial vacuum pressure of the vacuum chamber 20 is maintained at about 10⁻⁶ Torr by using a diffusion pump, which is a high-vacuum pump, and then argon gas is supplied from the gas supply systems 26 and 27 so that the pressure within the vacuum chamber 20 is maintained at 10⁻³ Torr when measured by the pressure gauge, thereby activating plasma. Then, negative DC bias is applied to the substrate support 21 from the DC bias power supply 25 so as to increase the probability that carbon ions existing within the plasma approach the substrate, thereby making it possible for the carbon thin-film to grow at a high rate. All the above-mentioned steps are performed at room temperature. The thin-film fabricated in this manner has a resistivity of not more than 5 mΩ·cm without any doping.

FIG. 3 shows an embodiment of a method for fabricating a laminated structure of a thin-film electroluminescent device 30 employing a carbon thin-film fabricated by a method of the present invention, as an electrode. As shown in FIG. 3, the method of the present embodiment includes the steps of: providing a transparent substrate (TCO or ITO glass) 31, forming a phosphor layer 32 on the top of the transparent substrate, forming an insulation film 33 on the top of the phosphor layer 32 through vacuum deposition, and finally forming a carbon thin-film electrode 34 through closed-field unbalanced magnetron sputtering. In FIG. 3, the transparent substrate 31 is a transparent ITO or TCO substrate, which is based on an In—O or Sn—O system. In addition, according to the present invention, the electrode is patterned through a metal shadow mask method. In addition, the insulation film 33 is formed by depositing Si₃N₄ or SiO₂ in a thickness of about 300 nm through PECVD (Plasma-Enhanced Chemical Vapor Deposition). In addition, if a phosphoric material is deposited in a thickness of about 600 nm to form the phosphor layer 32, which serves as a light emitting layer, a thin-film electroluminescent device is completed.

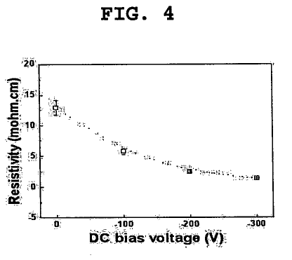

FIG. 4 shows an electric resistivity characteristic of a carbon thin-film 12 fabricated according to the present invention. From FIG. 4, it can be appreciated that the resistivity value decreases as the negative DC bias voltage increases. Apart from the low resistivity, the carbon thin-film has a smooth surface, high adhesive strength in relation to the substrate, and high strength. Furthermore, due to corrosion resistance and oxidation resistance, the carbon thin-film maintains a capability and a lifespan as an electrode for a long time. That is, the carbon thin-film fulfills a function as an electrode as well as a function as a protective coating, whereby a device employing the carbon thin-film has a lifespan longer than that of a device employing a metal electrode.

As described above, according to the present invention, a carbon thin-film with superior physical properties can be fabricated through closed-field unbalanced magnetron sputtering. Due to high strength, low frictional force, a smooth surface, low wear rate, and corrosion resistance which cannot be expected from a metallic film, the carbon thin-film can protect a substrate and a thin-film from oxidation and moisture, thereby increasing the lifespan as a thin-film and as an electrode. Consequently, the lifespan of the carbon thin-film as a component of a product or an electronic device can be increased. The employment of such a carbon thin-film as an electrode of a thin-film electroluminescent device can also contribute to enabling such a carbon thin-film to be fit for practical use so that the thin-film can be applied to various electronic devices as an electron-injecting layer of an LED, an electrode of a thin-film cell, a chemical sensor, or the like.

Although the present invention has been described above in relation to specific embodiments of fabricating of a carbon thin-film and an electroluminescent device for illustrative purposes, those skilled in the art will appreciate that various modifications, additions and substitutions are possible, without departing from the scope and spirit of the invention as disclosed in the accompanying claims.

What is claimed is:

1. A method of fabricating a carbon thin-film having high conductivity and high hardness by using a closed-field unbalanced magnetron sputtering apparatus.

2. The method as claimed in claim 1, wherein the closed-field unbalanced magnetron sputtering apparatus comprises:
a chamber including a substrate support means, a jig for fixing the substrate support means, a gas supply means, a DC bias power supply, and a cooling line; and
an evacuating means for maintaining a vacuum condition in the chamber.

3. The method as claimed in claim 2, wherein the closed-field unbalanced magnetron sputtering apparatus uses as a sputtering target a graphite target attached to an electromagnetic power unit.

4. The method as claimed in claim 2, wherein negative DC bias is applied to the jig so that carbon ions within plasma can easily arrive at the substrate.

5. The method as claimed in claim 2, comprising the steps of:
supplying argon (Ar) to the chamber as sputtering gas;
maintaining the initial vacuum of the chamber at about 10⁻⁶ Torr;
forming deposition pressure of about 10⁻³ Torr so as to activate plasma; and
applying negative DC bias to the substrate.

6. The method as claimed in claim 2, wherein the carbon thin-film has a thickness of about 200 nm.

7. The method as claimed in claim 2, wherein the sputtering is performed at room temperature.

8. The method as claimed in claim 2, wherein the carbon thin-film has resistivity of 5 mΩ·cm or lower.

9. A method of fabricating a carbon thin-film comprising the steps of:
mounting a flexible substrate on a substrate support within a vacuum chamber by forming the flexible substrate on a silicon or glass substrate and washing the flexible substrate with organic solvent;
maintaining the initial vacuum of the vacuum chamber at about 10⁻⁶ Torr and then supplying argon gas from a gas supply system;
maintaining pressure within the vacuum chamber at 10⁻³ Torr, thereby activating plasma; and
applying negative DC bias to the substrate support from a DC bias power supply so that carbon ions existing in the plasma can easily arrive at the flexible substrate, thereby forming a conductive carbon thin-film having a predetermined resistivity characteristic.

10. The method as claimed in claim 9, wherein the flexible substrate is selected from the group consisting of polyimide (Kapton), polyethylenenappthalate (PEN) and polyester (PET).

11. An electroluminescent device comprising as an electrode a carbon thin-film fabricated by the method of claim 1.

12. The electroluminescent device as claimed in claim 11, wherein the electroluminescent device is formed in a structure of a TCO or ITO glass/a phosphor/an insulator/a conductive thin-film electrode.

13. A method of fabricating a thin-film electroluminescent device comprising the steps of:
providing a transparent TCO or ITO substrate;
forming a phosphor layer on the top of the transparent substrate;
forming an insulation layer on the top of the phosphor layer through vacuum deposition; and
forming a carbon thin-film electrode through closed-field unbalanced magnetron sputtering.

14. The method as claimed in claim 13, wherein the transparent substrate is formed from an In—O or Sn—O system.

15. The method as claimed in claim 13, wherein the electrode is patterned by using metal shadow mask method.

16. The method as claimed in claim 13, wherein the insulation film is formed by depositing Si₃N₄ or SiO₂ in a thickness of about 300 nm through PECVD (plasma-enhanced chemical vapor deposition).

17. The method as claimed in claim 13, wherein the thickness of the phosphor layer deposited is about 600 nm.
